(19) United States
(12) Patent Application Publication
(10) Pub. No.: US 2014/0310568 A1
(43) Pub. Date: Oct. 16, 2014

(54) RECEIVER, COMMUNICATION DEVICE, AND COMMUNICATION METHOD

(71) Applicants: Wataru Matsumoto, Chiyoda-ku (JP); Yoshikuni Miyata, Chiyoda-ku (JP); Kenya Sugihara, Chiyoda-ku (JP)

(72) Inventors: Wataru Matsumoto, Chiyoda-ku (JP); Yoshikuni Miyata, Chiyoda-ku (JP); Kenya Sugihara, Chiyoda-ku (JP)

(73) Assignee: MITSUBISHI ELECTRIC CORPORATION, Chiyoda-ku (JP)

(21) Appl. No.: 14/359,402

(22) PCT Filed: Jan. 15, 2013
(86) PCT No.: PCT/JP2013/050568

§ 371 Date: May 20, 2014

(30) Foreign Application Priority Data
Mar. 26, 2012 (JP) 2012-069362

(51) Int. Cl. H03M 13/11

(52) U.S. Cl. CPC H03M 13/1105
USPC 714/752

(57) ABSTRACT

A Sum-product decoder 17 carries out soft-decision iterative decoding on a received signal s′(t) received by a signal receiving unit 12 by using an extended check matrix H_{d} which is a combination of a matrix D in which differential modulation by a differential modulator 3 is replaced by a check matrix and a check matrix H for error correcting codes to carry out error correction decoding on an information sequence bᵢ.

### FIELD OF THE INVENTION

The present invention relates to a receiver for, a communication device for, and a communication method of receiving a modulated signal of a codeword series outputted to a transmission line from a transmitter, carries out soft-decision iterative decoding on the received signal, and carries out error correction decoding on an information sequence.

### BACKGROUND OF THE INVENTION

A conventional communication device carries out establishment of phase synchronization by using, for example, a phase synchronization method disclosed by the following nonpatent reference 1. According to the synchronization method disclosed by the nonpatent reference 1, a transmitter prepares N signals (preambles or pilot signals) whose phases are inverted from each other and transmits these N signals, as shown in FIG. 4. When receiving the N signals outputted from the transmitter, a receiver detects the phase inversions from the N signals and uses a signal showing the phase inversions as a synchronization signal. More specifically, the receiver demodulates the data of a modulated wave in synchronization with the synchronization signal.

Usually, in order to detect phase inversions correctly and to be able to establish synchronization even in the case of a communication channel with many noises, the number N of signals needs to be set to be 10 or more in many cases. N signals whose phases are inverted from each other are transmitted before a data signal is transmitted or during a time interval between a time when a data signal is transmitted continuously and the next time when a data signal is transmitted continuously, so that synchronization is established.

Next, coding and decoding which use an LDPC (low-density parity-check) code will be explained. FIG. 5 is a block diagram showing a conventional communication device. Referring to FIG. 5, a coder and a modulator are components of a transmitter, and a demodulator and a Sum-product decoder are components of a receiver.

The coder of the transmitter prepares a check matrix H in advance, and, in the case in which the check matrix H is an LDGM (Low-Density Generation Matrix), and generates a codeword series C by using the check matrix H when receiving a message (b₁, b₂, . . . , bₖ) having an information length of k.

H=(n−k)×n

C={(b₁,b₂, . . . ,bₖ,p₁,p₂, . . . ,pₙ₋ₖ)

:H(b₁,b₂, . . . ,bₖ)^{t}=0}

where k is the information length and n is the codeword length. Further, p₁, p₂, . . . , and pₙ₋ₖ are a parity sequence.

After the coder generates a codeword series C, the modulator of the transmitter carries out digital modulation (e.g., modulation according to BPSK, QPSK, multi-valued QAM or the like) on the codeword series C, and transmits the modulated signal to the receiver via a communication channel. When receiving the modulated signal transmitted from the transmitter, the demodulator of the receiver carries out digital demodulation (e.g., demodulation according to BPSK, QPSK, multi-valued QAM, or the like) on the received signal. The Sum-product decoder of the receiver carries out soft-decision iterative decoding on the received signal while using the demodulated results acquired by the demodulator so as to estimate a message (b₁, b₂, . . . , bₖ) having the information length of k.

Although a portion for establishing phase synchronization is omitted in the communication device shown in FIG. 5, the structure of a communication device equipped with a portion for establishing phase synchronization is as shown in FIG. 6. However, an example of handling a synchronization unit and an error correcting unit independently is shown in the communication device of FIG. 6. FIG. 7 is an explanatory drawing showing a frame structure applied to the communication device of FIG. 6. In the communication device of FIG. 6, after the synchronization unit completes symbol synchronization during a preamble and fixes the synchronous phase to the estimated phase which is the result of the symbol synchronization, frame synchronization according to a unique word is carried out and, after that, a decoding process of decoding an LDPC code is carried out. Therefore, the decoding performance for decoding an LDPC code depends on errors in the estimated phase of the symbol synchronization.

Hereafter, the processing carried out by the communication device of FIG. 6 will be explained concretely.

First, parameters regarding a system model are defined. Hereafter, it is assumed that an AWGN transmission line is provided as a communication channel. When receiving an information sequence bᵢ which is a message (b₁, b₂, . . . , bₖ), an LDPC coder carries out error correction coding on the information sequence bᵢ so as to generate a codeword series C.

bᵢε{0,1},i=1,2, . . . , and L_{c}

C={(b₁,b₂, . . . ,bₖ,p₁,p₂, . . . ,pₙ₋ₖ)

:H(b₁,b₂, . . . ,bₖ)^{t}=0}

After the LDPC coder generates a codeword series C, a modulator generates a transmission signal uᵢ from the information sequence bᵢ which is the elements of the codeword series C and a parity sequence pₙ₋ₖ, as shown in the following equation (1).

$$For$$

$$1 \leq i \leq k$$

$${u}_{i} = \{ \begin{matrix}1 & ( {b}_{i} = 0 ) \\ - 1 & ( {b}_{i} = 1 ) ,\end{matrix} \\ For \\ k < i \leq n \\ {u}_{i} = \{ \begin{matrix}1 & ( {p}_{i - k} = 0 ) \\ - 1 & ( {p}_{i - k} = 1 )\end{matrix}$$

After generating the transmission signal uᵢ, the modulator generates a codeword series cₖ (k=1, 2, . . . , L_{c}/2) from the transmission signal uᵢ, as shown in the following equation (2).

cₖ=u₂ₖ₋₁+j·u₂ₖ (2)

After generating a codeword series cₖ from the transmission signal uᵢ, the modulator carries out QPSK modulation on the codeword series cₖ, and outputs the QPSK modulated signal s (t), as shown in the following equation (3), to the AWGN transmission line.

s(t)=Re[cₖ·e^{-j2πf}^{_{c}}^{t}]

t=Tₛ·i,(i=1,2, . . . ,2k−1,2k, . . . ,L_{c})

Tₛ=1/(4f_{c}) (3)

where Re shows the real part, f_{c} shows a carrier frequency, t shows a time, and Tₛ shows a sample interval. The modulator outputs the QPSK modulated signal s (t) to the AWGN transmission line in the order of t=Tₛ·i (i=1, 2, . . . , 2k−1, 2k, . . . , and L_{c}). FIG. 8 is an explanatory drawing showing the transmission sequence on a time axis.

It is assumed that the AWGN transmission line is exposed to an additive white Gaussian noise (AWGN) nₖ during transmission of the QPSK modulated signal s (t).

E[|nₖ|²]=2σ₀²

where σ₀² is the variance of the Gaussian noise. Further, it is assumed that because a phase error θ due to sample point errors in the transmitter and the receiver and a carrier wave frequency error Δφ due to a frequency error in an oscillator disposed between the transmitter and the receiver are added to the QPSK modulated signal s (t), a modulated signal as shown in the following equation (4) is received by the receiver as a received signal s′(t).

s′(t)=Re{[e^{j(θ+Δφ·k)}cₖ·e^{-j2πf}^{_{c}}^{t}]e^{-j2πf}^{_{c}}^{t′}} (4)

The demodulator of the receiver demodulates the received signal s′(t) at the sample intervals of Tₛ and in the order of t=Tₛ·i (i=1, 2, . . . , 2k−1, 2k, . . . , and L_{c}), and acquires a received codeword sequence yₖ as shown in the following equation (5).

yₖ=e^{j(θ-Δφ·k)}cₖ+nₖ=r₂ₖ₋₁+j·r₂ₖ (5)

where r₂ₖ₋₁ and r₂ₖ are complex elements of the received codeword sequence yₖ.

When receiving the received codeword sequence yₖ from the demodulator, the Sum-product decoder of the receiver carries out soft-decision iterative decoding on the received signal s′(t) while using the received codeword sequence yₖ, and carries out error correction decoding on the information sequence bᵢ. As a result, a message (b₁, b₂, . . . , bₖ) is outputted from the Sum-product decoder. [The decoding performance for decoding an LDPC code according to phase errors]

FIG. 9 is an explanatory drawing showing the LDPC decoding characteristics in a state in which a fixed phase error exists. It can be seen that although up to about 10 degrees of fixed phase error can be permitted if the amount of Eb/N₀ degradation resulting from a fixed phase error phi which can achieve both the bit error rate characteristics required for the communication device and the frame error rate required for the communication device is 0.5 dB (Eb/N₀≈2 dB) when the bit error rate characteristics is BER=10⁻⁴ and the frame error rate is FER=10⁻², the degradation becomes large when the fixed phase error is larger than about 10 degrees.

For example, when the communication device carries out optical communications, remarkable phase variations occur and hence this results in a major factor of degradation, as shown in FIG. 9. Therefore, there are many cases in which in a communication device or the like that carries optical communications, a differential modulator (refer to FIG. 10) having strong resistance to phase variations is mounted in a transmitter, and digital modulation is carried out on a codeword sequence cₖ.

### RELATED ART DOCUMENT

### Nonpatent reference

Nonpatent reference 1: Matsumoto and Imai, “Blind Synchronization Scheme with Low-Density Parity-Check (LDPC) Codes”, the Institute of Electronics, Information and Communication Engineers Paper Magazine B Vol.J86-B No. 10 pp. 2065-2078 October, 2003

### SUMMARY OF THE INVENTION

### Problems to be Solved by the Invention

Because conventional communication devices are constructed as above, mounting a differential modulator having strong resistance to phase variations in a transmitter in the case in which remarkable phase variations occur can reduce the influence of phase variations. However, in the case in which a transmitter includes a differential modulator, when a receiver carries out differential detection, if, for example, a 1-bit bit error occurs, this bit error is doubled and becomes a 2-bit bit error. A problem is therefore that there occurs degradation of about 3 dB of SNR ratio to the bit error rate (BER) after the detection.

The present invention is made in order to solve the above-mentioned problem, and it is therefore an object of the present invention to provide a receiver, a communication device, and a communication method capable of preventing degradation in the SNR ratio to the bit error rate even though a differential modulator having strong resistance to phase variations is mounted in a transmitter.

### Means for Solving the Problem

In accordance with the present invention, there is provided a receiver in which a signal receiver that receives a modulated signal of a codeword series outputted from a transmitter to a transmission line is disposed, and an error correction decoder carries out soft-decision iterative decoding on the received signal received by the signal receiver by using an extended check matrix which is a combination of a matrix in which differential modulation carried out by the transmitter is replaced by a check matrix and a check matrix for error correcting codes to carry out error correction decoding on an information sequence.

### Advantages of the Invention

Because according to the present invention, the signal receiver that receives a modulated signal of a codeword series outputted from the transmitter to the transmission line is disposed, and the error correction decoder carries out soft-decision iterative decoding on the received signal received by the signal receiver by using the extended check matrix which is a combination of the matrix in which the differential modulation carried out by the transmitter is replaced by a check matrix and the check matrix for error correcting codes to carry out error correction decoding on the information sequence, there is provided an advantage of being able to prevent degradation in the SNR ratio to the bit error rate even though a differential modulator having strong resistance to phase variations is mounted in the transmitter.

### BRIEF DESCRIPTION OF THE FIGURES

FIG. 1 is a block diagram showing a communication device in accordance with Embodiment 1 of the present invention;

FIG. 2 is a block diagram showing processing (communication method) carried out by the communication device in accordance with Embodiment 1 of the present invention;

FIG. 3 is an explanatory drawing showing a relationship between a received signal and a regression line;

FIG. 4 is an explanatory drawing showing a synchronization method disclosed by nonpatent reference 1;

FIG. 5 is a block diagram showing a conventional communication device;

FIG. 6 is a block diagram showing a communication device equipped with a portion in which phase lock is established;

FIG. 7 is an explanatory drawing showing a frame structure applied to the communication device shown in FIG. 6.

FIG. 8 is an explanatory drawing showing a transmission sequence on a time axis.

FIG. 9 is an explanatory drawing showing LDPC decoding characteristics in a state in where a fixed phase error exists; and

FIG. 10 is a block diagram showing a differential modulator.

### EMBODIMENTS OF THE INVENTION

Hereafter, in order to explain this invention in greater detail, the preferred embodiments of the present invention will be described with reference to the accompanying drawings. Embodiment 1.

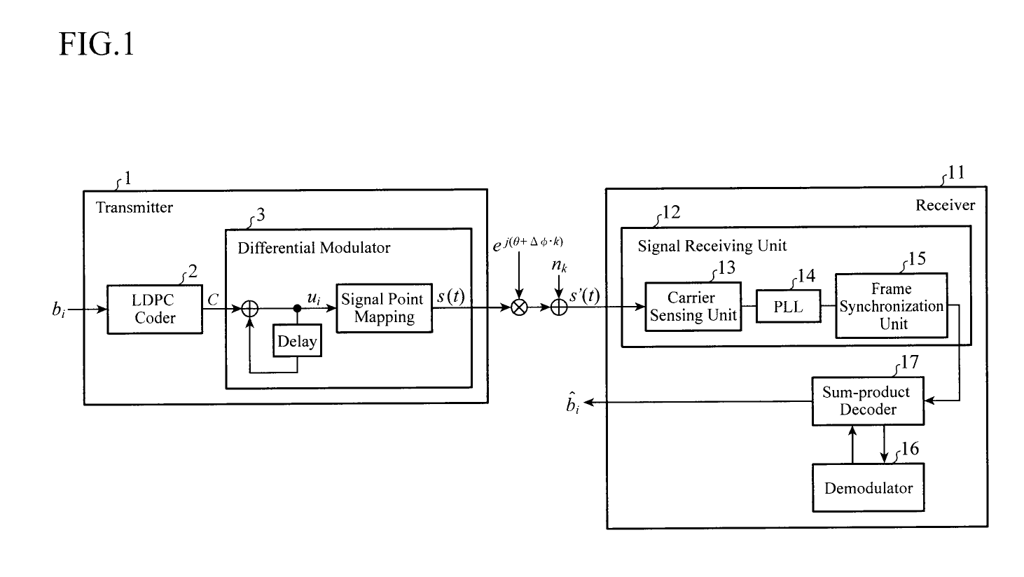

FIG. 1 is a block diagram showing a communication device in accordance with Embodiment 1 of the present invention. Referring to FIG. 1, a transmitter 1 is comprised of an LDPC coder 2 and a differential modulator 3. The LDPC coder 2 of the transmitter 1 carries out a process of performing error correction coding on an information sequence so as to generate a codeword series. The differential modulator 3 of the transmitter 1 carries out a process of performing differential modulation on the codeword series generated by the LDPC coder 2, and outputting a modulated signal of the codeword series to a transmission line.

A receiver 11 is comprised of a signal receiving unit 12, a demodulator 16, and a Sum-product decoder 17. The signal receiving unit 12 is comprised of a carrier sensing unit 13, a PLL (Phase Locked Loop) 14, and a frame synchronization unit 15, and carries out a process of receiving the modulated signal of the codeword series outputted from the transmitter 1 to the transmission line. The signal receiving unit 12 constructs a signal receiver.

The carrier sensing unit 13 carries out a process of detecting the modulated signal of the codeword series outputted from the transmitter 1 to the transmission line. The PLL 14 is a phase locked loop and is a circuit that establishes phase synchronization of the received signal which is the modulated signal detected by the carrier sensing unit 13. The frame synchronization unit 15 is a circuit that recognizes a start of significant data when detecting a predetermined bit pattern from the received signal in order to establish synchronization between the transmit side and the receive side.

The demodulator 16 carries out a process of demodulating the received signal received by the signal receiving unit 12. The Sum-product decoder 17 is an error correction decoder that carries out soft-decision iterative decoding on the received signal received by the signal receiving unit 12 by using an extended check matrix H_{d} which is a combination of a matrix D in which the differential modulation by the differential modulator 3 is replaced by a check matrix and a check matrix H for error correcting codes to carry out error correction decoding on an information sequence. An error correction decoder is comprised of the demodulator 16 and the Sum-product decoder 17.

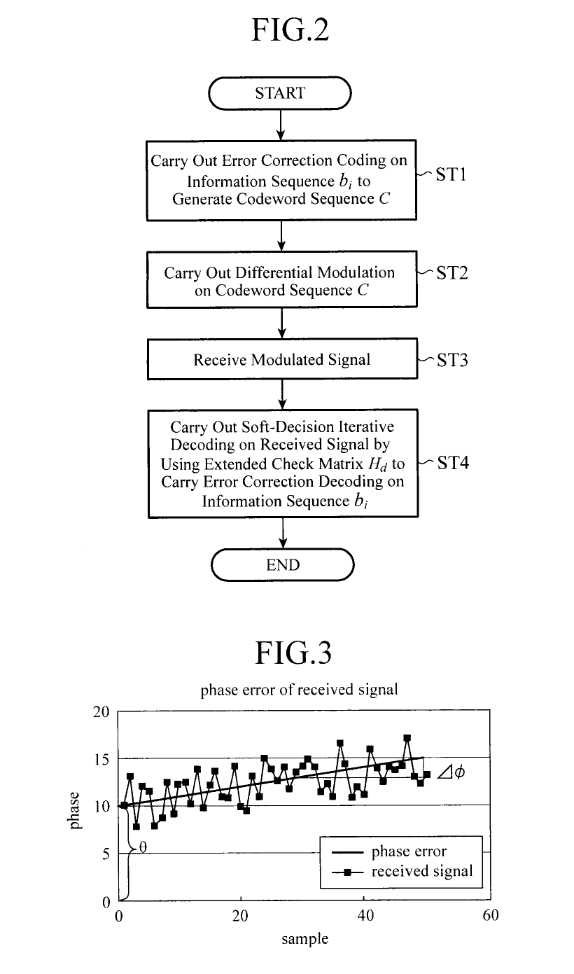

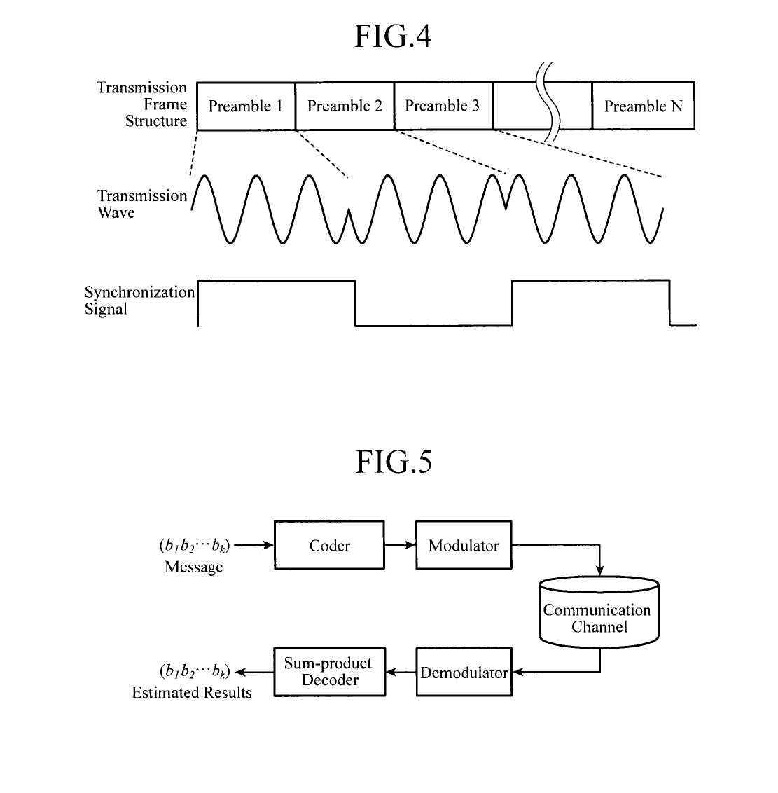

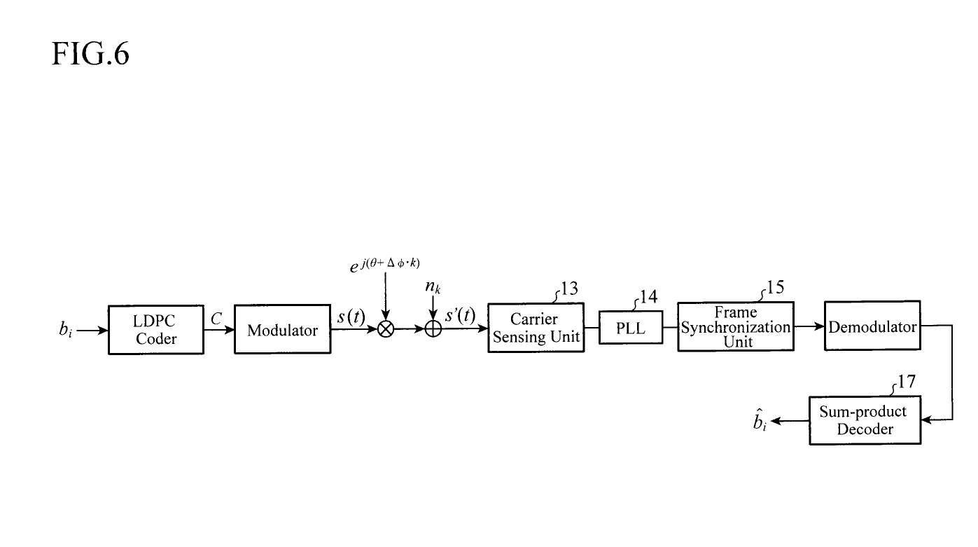

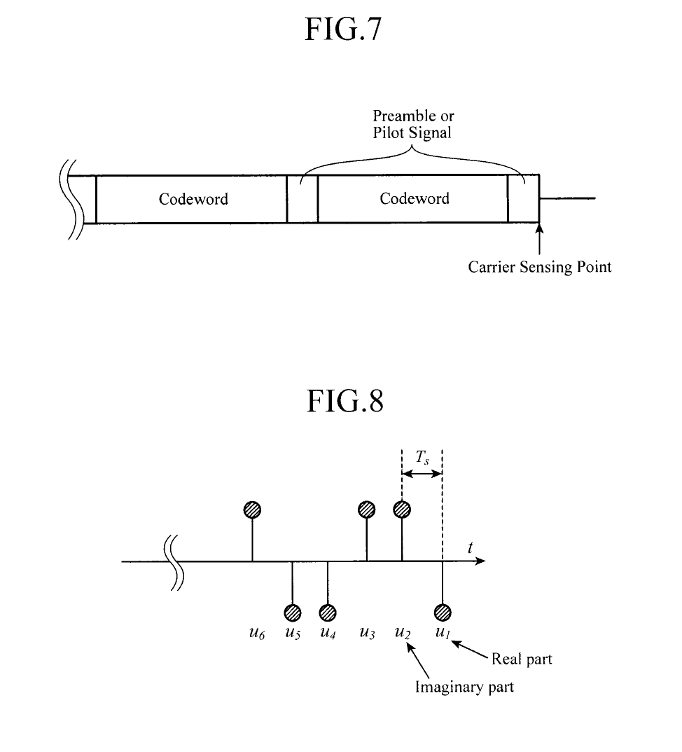

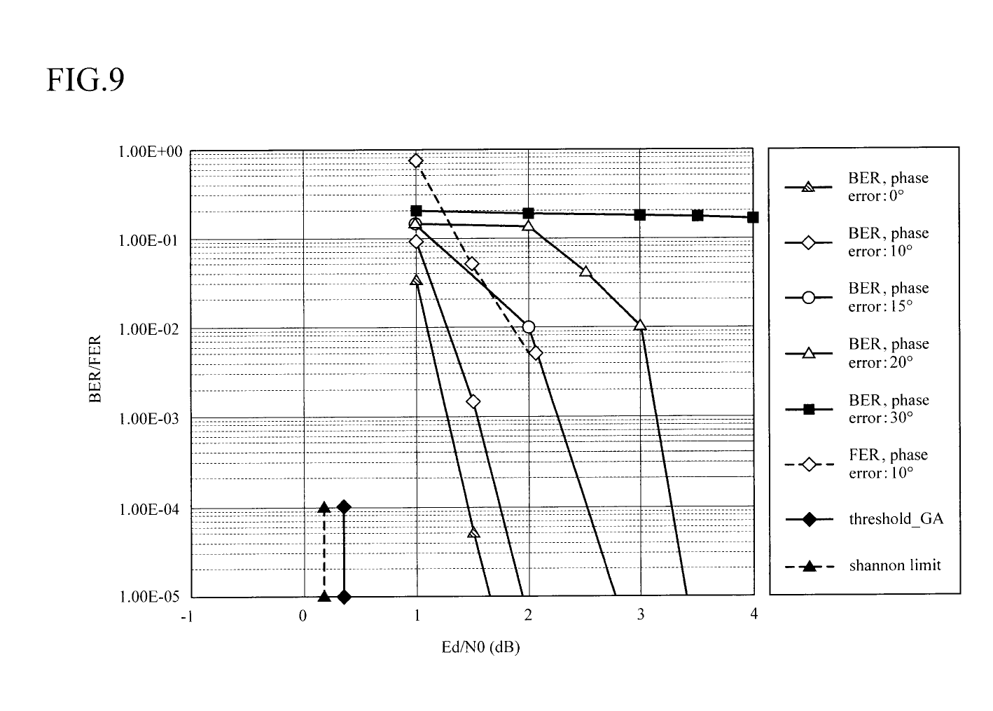

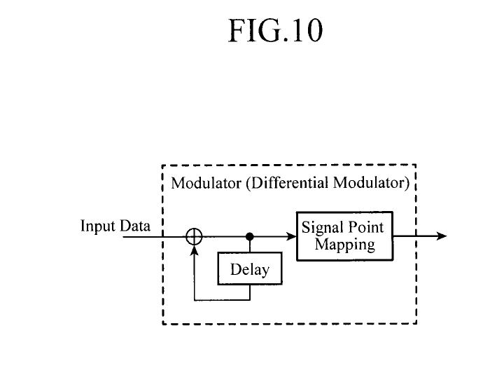

In the example shown in FIG. 1, although it is assumed that the LDPC coder 2, the differential modulator 3, the signal receiving unit 12, the demodulator 16, and the Sum-product decoder 17 which are the components of the communication device consist of hardware for exclusive use (e.g., a semiconductor integrated circuit equipped with a CPU, a one chip microcomputer or the like), each of the transmitter 1 and the receiver 11 can alternatively consist of a computer. In the case in which the transmitter 1 consists of a computer, a program in which the processes carried out by the LDPC coder 2 and the differential modulator 3 are described can be stored in a memory of the computer, and a CPU of the computer can be made to execute the program stored in the memory. Further, in the case in which the receiver 11 consists of a computer, a program in which the processes carried out by the signal receiving unit 12, the demodulator 16, and the Sum-product decoder 17 are described can be stored in a memory of the computer, and a CPU of the computer can be made to execute the program stored in the memory. FIG. 2 is a block diagram showing processing (communication method) carried out by the communication device in accordance with Embodiment 1 of the present invention.

Next, the operation of the communication device will be explained. In this Embodiment 1, there is proposed a method of, in order to carry out recovery of degradation in the synchronization performance due to a phase error and a carrier wave frequency error on the condition that the transmitter 1 carries out differential modulation, estimating the phase error and the carrier wave frequency error by using a new LDPC decoding method corresponding to a check matrix taking into consideration differential modulation in a state in which synchronization cannot be established for the sample timing and the carrier frequency, thereby enhancing the error correction ability.

To this end, in accordance with this Embodiment 1, the differential modulation which the transmitter 1 carries out is expressed by a check matrix, and decoding is enabled by means of LDPC decoding or turbo decoding. More specifically, while a conventional communication device carries out decoding by using only a check matrix H of LDPC codes, the communication device in accordance with this Embodiment 1 carries out the decoding by using an extended check matrix H_{d} which is a combination of a matrix D in which the differential modulation is replaced by a check matrix and a check matrix H for error correcting codes.

$${H}_{d} = [ \frac{I \vert D}{H \vert 0} ] \qquad ( 6 )$$

where D is the check matrix corresponding to the differential modulation, I is a unit matrix, 0 is a zero matrix, and H is the check matrix for error correcting codes.

In this case, when the differential modulation which the transmitter 1 carries out is, for example, differential BPSK, a concrete example of the extended check matrix H_{d} is given by the following equation (7). A codeword sequence for the extended check matrix H_{d} is shown above the equation (7). The codeword sequence consists of an information sequence b, a parity sequence P, and a transmission codeword sequence U, and the sequence outputted from the transmitter 1 to the transmission line is only the transmission codeword sequence U.

Codeword Sequence for Proposed Check Matrix Shown Below

$$\begin{matrix}Information Sequence b & P & Transmission Code Sequence U \\ & & \end{matrix} \\ {H}_{d} = \begin{matrix}1 & & & & & & & & 1 & & & & & & & 1 \\ & 1 & & & & & & & 1 & 1 & & & & & & \\ & & 1 & & & & & & & 1 & \backslash & & & & & \\ & & & \backslash & & & & & & & \backslash & 1 & & & & \\ & & & & 1 & & & & & & & 1 & 1 & & & \\ & & & & & 1 & & & & & & & 1 & 1 & & \\ & & & & & & 1 & & & & & & & 1 & 1 & \\ & & & & & & & 1 & & & & & & & 1 & 1 \\ & & & & & & & & & & & & & & & \\ & & & & & & & & & & & & & & & \\ & & & H & & & & & & & & 0 & & & & \\ & & & & & & & & & & & & & & & \\ & & & & & & & & & & & & & & & \end{matrix} \qquad ( 7 )$$

Further, when the differential modulation which the transmitter 1 carries out is, for example, differential QPSK, a concrete example of the extended check matrix H_{d} is given by the following equation (8). A codeword sequence for the extended check matrix H_{d} is shown above the equation (8). The codeword sequence consists of an information sequence b, a parity sequence P, and a transmission codeword sequence U, and the sequence outputted from the transmitter 1 to the transmission line is only the transmission codeword sequence U.

Codeword Sequence for Proposed Check Matrix Shown Below

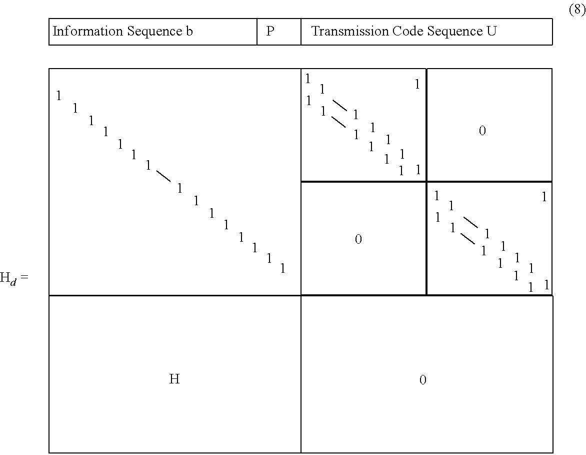

Therefore, because the receiver 11 receives the log-likelihood ratio of the received value to the transmission codeword sequence U, but does not receive anything regarding the information sequence b and the parity sequence P, the receiver carries out calculation by receiving a state in which both the probability of “1” and the probability of “0” are 50% (log-likelihood ratio=zero value) as an input. Particularly, in a concrete calculation which will be mentioned below, the value of the information sequence b is estimated by using a decoding method of decoding LDPC from the log-likelihood ratio of the received value to the transmission codeword sequence U. In this Embodiment 1, although a method of carrying out a sum-product algorithm using the above-mentioned extended check matrix H_{d} is used, in accordance with this method, the same performance can be offered by using either of a probability domain sum-product decoding method and a logarithm domain sum-product decoding method. In this Embodiment 1, although for convenience' sake, an explanation will be made by assuming that a logarithm domain sum-product decoding method is used, it is needless to say that a probability domain sum-product decoding method can be alternatively used. Further, although an example of using LDPC codes will be explained in this Embodiment 1, any decoding method can be applied as long as the decoding method is an LDPC decoding method,

Hereafter, the processing carried out by the communication device of FIG. 1 will be explained concretely. Hereafter, it is assumed that an AWGN transmission line is provided as the communication channel. First, when receiving an information sequence bᵢ which is a message (b₁, b₂, . . . , bₖ) having an information length of k, the LDPC coder 2 of the transmitter 1 carries out error correction coding on the information sequence bᵢ so as to generate a codeword sequence C (an information sequence b+a parity sequence P+a transmission code sequence U) (step ST1 of FIG. 2).

C={(b₁,b₂, . . . ,bₖ,p₁,p₂, . . . ,pₙ₋ₖ)

:H(b₁,b₂, . . . ,bₖ)^{t}=0}

After the LDPC coder 2 generates the codeword sequence C, the differential modulator 3 of the transmitter 1 carries out differential modulation on the codeword sequence C, and outputs a modulated signal s(t) of the codeword sequence C to the transmission line (step ST2).

More specifically, when carrying out differential modulation on the codeword sequence C, the differential modulator 3 determines a transmission code sequence uᵢ from the information sequence bᵢ and the parity sequence pᵢ which are included in the codeword sequence C, as shown in the following equation (9).

$$( 1 ) When 1 \leq i \leq k \\ {v}_{i} = ( {b}_{i} + {b}_{i - 1} ) mod 2 \\ ( 2 ) When i = k + 1 \\ {v}_{i} = ( {p}_{i - k} + {b}_{i - 1} ) mod 2 \\ ( 3 ) When k + 2 \leq i \leq n \\ {v}_{i} = ( {p}_{i - k} + {p}_{i - k - 1} ) mod 2 \\ {u}_{i} = \{ \begin{matrix}1 & ( {v}_{i} = 0 ) \\ - 1 & ( {v}_{i} = 1 )\end{matrix} \qquad ( 9 )$$

After determining the transmission code sequence uᵢ, the differential modulator 3 generates a codeword sequence cₖ from the transmission code sequence uᵢ, as shown in the following equation (10).

cₖ=u₂ₖ₋₁+j·u₂ₖ (10)

After generating the codeword sequence cₖ from the transmission signal uᵢ, the differential modulator 3 carries out QPSK modulation on the codeword sequence cₖ, and outputs a QPSK modulated signal s(t) as shown in the following equation (11) to the AWGN transmission line. In this embodiment, although the differential modulator carries out QPSK modulation on the codeword sequence cₖ, the modulation is not limited to QPSK modulation and, for example, the differential modulator can carry out BPSK modulation on the codeword sequence cₖ.

s(t)=Re[cₖ·e^{-j2πf}^{_{c}}^{t}]

t=Tₛ·i,(i=1,2, . . . ,2k−1,2k, . . . ,L_{c})

Tₛ=1/(4f_{c}) (11)

where Re shows the real part, f_{c} shows the carrier frequency, t shows the time, and Tₛ shows the sample interval. The differential modulator 3 outputs the QPSK modulated signal s(t) to the AWGN transmission line in the order of t=Tₛ·i (i=1, 2, . . . , 2k−1, 2k, . . . , and L_{c}). FIG. 8 shows the transmission sequence on a time axis.

It is assumed that the AWGN transmission line is exposed to an additive white Gaussian noise (AWGN) nₖ during transmission of the QPSK modulated signal s(t).

E[|nₖ|²]=2σ₀²

where σ₀² is the variance of the Gaussian noise. Further, it is assumed that because a phase error θ due to sample point errors in the transmitter 1 and the receiver 11 and a carrier wave frequency error Δφ due to a frequency error in an oscillator disposed between the transmitter 1 and the receiver 11 are added to the QPSK modulated signal s(t), a modulated signal as shown in the following equation (12) is received by the receiver 11 as a received signal s′(t).

When the signal receiving unit 12 receives the modulated signal shown in the equation (12) as the received signal s′(t) (step ST3), the Sum-product decoder 17 of the receiver 11 carries out soft-decision iterative decoding on the received signal s′(t) received by the signal receiving unit 12 by using the extended check matrix H_{d} which is a combination of the matrix D in which the differential modulation by the differential modulator 3 is replaced by a check matrix and the check matrix H for error correcting codes to carry out error correction decoding on the information sequence bᵢ (step ST4).

Hereafter, the processing carried out by the demodulator 16 and the Sum-product decoder 17 will be explained concretely. The processing is divided roughly into (A) a phase error correcting process using soft decision, and (B) a typical Sum-product decoding process.

### (A) The Phase Error Correcting Process Using Soft Decision (First Step)

### (A-1) Initialization

First, a pseudo-posterior log-likelihood ratio to the information sequence bᵢ after the l_{A}-th time iterative decoding in the logarithm domain Sum-product decoding which is carried out in the following (A-2) is set to Lᵤ^{lA}(bᵢ). Further, a pseudo-posterior log-likelihood ratio to the parity sequence pᵢ after the l_{A}-th time iterative decoding in the logarithm domain Sum-product decoding which is carried out in (A-2) is set to Lᵤ^{lA}(pᵢ). Further, a pseudo-posterior log-likelihood ratio to the transmission code sequence uᵢ after the l_{A}-th time iterative decoding in the logarithm domain Sum-product decoding which is carried out in (A-2) is set to Lᵤ^{lA}(uᵢ). However, only an initial value Lᵤ⁰ (uᵢ) of the pseudo-posterior log-likelihood ratio to the transmission code sequence uᵢ is set to the log-likelihood ratio acquired from the AWGN communication channel, as shown in the following equation (13).

In this case, the initial values Lᵤ⁰(uᵢ) and Lᵤ⁰(vᵢ) are given by the following equation (14).

$${L}_{u}^{0} ( {u}_{i} ) = {L}_{u}^{0} ( {v}_{i} ) := ln \frac{Pr \{ {v}_{i} = 0 \vert r \}}{Pr \{ {v}_{i} = 1 \vert r \}} \qquad ( 14 )$$

Further, an initial value Lᵤ⁰(bᵢ) of the pseudo-posterior log-likelihood ratio to the information sequence bᵢ is set as shown in the following equation (15).

$${L}_{u}^{0} ( {b}_{i} ) := ln \frac{Pr \{ {b}_{i} = 0 \vert r \}}{Pr \{ {b}_{i} = 1 \vert r \}} = 0 \qquad ( 15 )$$

In addition, an initial value Lᵤ⁰(pᵢ) of the pseudo-posterior log-likelihood ratio to the parity sequence pᵢ is set as shown in the following equation (16).

$${L}_{u}^{0} ( {p}_{i} ) := ln \frac{Pr \{ {p}_{i} = 0 \vert r \}}{Pr \{ {p}_{i} = 1 \vert r \}} = 0 \qquad ( 16 )$$

where the variance of the AWGN noise is expressed by σ₀², and the block of the received symbol is expressed by r: [r₁, r₂, . . . , r_{Le}]. Further, a variable l_{A} showing an initial iteration counter is set to “1”, and a variable showing a maximum number of iterations is set to l_{A}^{max}.

### (A-2) Logarithm Domain Sum-Product Decoding

Assuming that the pseudo-posterior log-likelihood ratio Lᵤ^{lA}(uᵢ) to the transmission code sequence uᵢ, other than the initial value Lᵤ⁰(bᵢ), is the log-likelihood ratio of the communication channel after the phase error correction is carried out in (A-3) to (A-6), which will be mentioned below, the Sum-product decoder 17 carries out logarithm domain Sum-product decoding only once by using the extended check matrix H_{d}.

### (A-3) Calculation of a Soft Decision Bit

After carrying out the logarithm domain Sum-product decoding, the Sum-product decoder 17 estimates a soft decision bit uₖ hat (because the symbol of “̂” attached to the top of the characters of uₖ cannot be written in the text because this application is an electronic one, a character string to which the symbol is attached is written as “uₖ hat”) by using Lᵤ^{lA}(uₖ) of the coded signal {uₖ}ₖ₋₁^{Lc} after l_{A} iterations, as shown in the following equation (17).

$${\hat{u}}_{k} := E \{ {u}_{k} \} = Pr \{ {u}_{k} = + 1 \} \cdot Pr \{ {u}_{k} = - 1 \} \cdot ( - 1 ) = \frac{exp ( {L}_{u}^{{1}_{A}} ( {u}_{k} ) )}{1 + exp ( {L}_{u}^{{1}_{A}} ( {u}_{k} ) )} + \frac{- 1}{1 + exp ( {L}_{u}^{{1}_{A}} ( {u}_{k} ) )} = tanh ( \frac{{L}_{u}^{{1}_{A}} ( {u}_{k} )}{2} ) \qquad ( 17 )$$

### (A-4) Estimation of a Phase Error Using a Minimum Mean Square Error (MMSE) Method

The Sum-product decoder 17 carries out estimation of a phase error using MMSE as follows. First, an estimated phase error is expressed by θ hat, and an estimated carrier wave frequency error is expressed by Δφ hat.

$$\hat{θ} ( - π < \hat{θ} \leq π )$$

$$Δ \hat{φ} ( - \frac{2 π}{{T}_{s}} < Δ \hat{φ} \leq \frac{2 π}{{T}_{s}} )$$

The Sum-product decoder 17 assumes that the following equation (18) is a regression line of k, and calculates the estimated phase error θ hat and the estimated carrier wave frequency error Δφ hat which satisfy the following equation (19).

$$\begin{matrix}\hat{θ} + Δ \hat{φ} \cdot k & ( 18 ) \\ \hat{θ} + Δ \hat{φ} \cdot k = arg {min}_{\hat{θ} , Δ \hat{φ}} E \{ {\vert {tan}^{- 1} \frac{{\hat{u}}_{2 k}}{{\hat{u}}_{2 k - 1}} - ( \hat{θ} + Δ \hat{φ} \cdot k ) \vert}^{2} \} & ( 19 )\end{matrix}$$

In this case, a soft decision codeword sequence having complex representation using the soft decision bit uₖ hat is expressed by c hat.

ĉₖ=û₂ₖ₋₁+j·û₂ₖ

In this case, the phase error estimated using the soft decision bit uₖ hat is shown as in the following equation (20).

$${tan}^{- 1} \frac{Im [ {y}_{k} / {\hat{c}}_{k} ]}{Re [ {y}_{k} / {\hat{c}}_{k} ]} \qquad ( 20 )$$

where Re[•] shows the real part and Im[•] shows the imaginary part.

In order to calculate the estimated phase error θ hat and the estimated carrier wave frequency error Δφ hat which satisfy the equation (19), what is necessary is just to solve the simultaneous equation acquired by partially differentiating the following equation (21) with θ hat and Δφ hat and putting the results of the partial differentiations to be equal to 0 respectively.

$$S = {\sum }_{k = 1}^{{L}_{c} / 2} {( {tan}^{- 1} \frac{Im [ {y}_{k} / {c}_{k} ]}{Re [ {y}_{k} / {c}_{k} ]} - ( \hat{θ} + \hat{θ} \cdot k ) )}^{2} \qquad ( 21 )$$

More specifically, by solving the simultaneous equation given by the following equations (22) and (23), the estimated phase error θ hat and the estimated carrier wave frequency error Δφ hat can be calculated.

$$\begin{matrix}\frac{\partial S}{\partial \hat{θ}} = - 2 {\sum }_{k - 1}^{{L}_{c} / 2} ( {tan}^{- 1} \frac{Im [ {y}_{k} / {c}_{k} ]}{Re [ {y}_{k} / {c}_{k} ]} - ( \hat{θ} + Δ \hat{φ} \cdot k ) ) = 0 & ( 22 ) \\ \frac{\partial S}{\partial \hat{φ}} = - 2 k {\sum }_{k = 1}^{{L}_{c} / 2} ( {tan}^{- 1} \frac{Im [ {y}_{k} / {c}_{k} ]}{Re [ {y}_{k} / {c}_{k} ]} - ( \hat{θ} + Δ \hat{φ} \cdot k ) ) = 0 & ( 23 )\end{matrix}$$

FIG. 3 shows a relationship between the received signal yₖ and the regression line of the equation (18), and the phase error of the received signal yₖ draws an estimated straight line (straight line of phase error) as shown in FIG. 3.

### (A-5) Correction of the Phase Error Using a Soft Decision Bit

After the Sum-product decoder 17 calculates the estimated phase error θ hat and the estimated carrier wave frequency error Δφ hat, the demodulator 16 carries out a phase error correction and a carrier wave frequency error correction on the received signal yₖ by using the estimated phase error θ hat and the estimated carrier wave frequency error Δφ hat so as to calculate a corrected received signal yₖ hat.

$$\begin{matrix}{\hat{y}}_{k} = {y}_{k} \cdot {e}^{- j ( θ + Δ φ \cdot k )} = ( {r}_{2 k - 1} + j \cdot {r}_{2 k} ) \cdot ( cos ( θ + Δ φ \cdot k ) - j \cdot sin ( θ + Δ φ \cdot k ) ) & ( 24 ) \\ {\hat{r}}_{2 k - 1} = Re \{ ( {r}_{2 k - 1} + j \cdot {r}_{2 k} ) \cdot ( cos ( θ + Δ φ \cdot k ) - j \cdot sin ( θ + Δ φ \cdot k ) ) \} & ( 25 ) \\ {\hat{r}}_{2 k} = Im \{ ( {r}_{2 k - 1} + j \cdot {r}_{2 k} ) \cdot ( cos ( θ + Δ φ \cdot k ) - j \cdot sin ( θ + Δ φ \cdot k ) ) \} & ( 26 )\end{matrix}$$

### (A-6) Update of LLR

After the demodulator 16 calculates the corrected received signal yₖ hat, the Sum-product decoder 17 calculates the pseudo-posterior log-likelihood ratio Lᵤ^{lA}(uᵢ) to the transmission code sequence uᵢ by temporarily correcting the phase error by using a soft decision bit, as shown in the following equation (27).

$${L}_{u}^{{l}_{A}} ( {u}_{i} ) := ln \frac{Pr \{ {u}_{i} = + 1 \vert \hat{r} \}}{Pr \{ {u}_{i} = - 1 \vert \hat{r} \}} = \frac{2 {\hat{r}}_{i}}{{σ}_{0}^{2}} \qquad ( 27 )$$

where \hat{r} is the block of an estimated received symbol, and is \hat{r}:=[\hat{r}₁, \hat{r}₂, . . . , \hat{r}_{L}_{_{c}}]^{T}.

### (B) Typical Sum-Product Decoding Process (Second Step)

(B-1) Initialization after Frame Synchronization

First, a pseudo-posterior log-likelihood ratio to the information sequence bᵢ after the l_{B}-th time iterative decoding in the typical logarithm domain Sum-product decoding in the second step is set to Lᵤ^{lB}(bᵢ). Further, a pseudo-posterior log-likelihood ratio to the parity sequence pᵢ after the l_{B}-th time iterative decoding in the typical logarithm domain Sum-product decoding is set to Lᵤ^{lB}(pᵢ). Further, a pseudo-posterior log-likelihood ratio to the transmission code sequence uᵢ after the l_{B}-th time iterative decoding in the typical logarithm domain Sum-product decoding is set to Lᵤ^{lB}(uᵢ).

Initial values of the pseudo-posterior log-likelihood ratios in the second step are set up as follows.

Lᵤ^{lB=0}(bᵢ)=Lᵤ^{lA}(bᵢ)

Lᵤ^{lB=0}(pᵢ)=Lᵤ^{lA}(pᵢ)

Lᵤ^{lB=0}(uᵢ)=Lᵤ^{lA}(uᵢ)

Further, a variable l_{B} showing an initial iteration counter in the second step is set to “1”, and a variable showing a maximum number of iterations is set to l_{B}^{max}.

### (B-2) Sum-Product Decoding

The Sum-product decoder 17 carries out logarithm domain Sum-product decoding only once by using the pseudo-posterior log-likelihood ratios Lᵤ^{lB}(bᵢ), Lᵤ^{lB}(pᵢ), and Lᵤ^{lB}(uᵢ) and the extended check matrix H_{d}. The Sum-product decoder 17 outputs a temporary estimated word as the results of the logarithm domain Sum-product decoding.

$$Temporary estimated word ( {\hat{b}}_{1} , {\hat{b}}_{2} , … , {\hat{b}}_{{L}_{h}} , {\hat{p}}_{1} , {\hat{p}}_{2} , … , {\hat{p}}_{{L}_{p}} , {\hat{v}}_{1} , {\hat{v}}_{2} , … , {\hat{v}}_{{L}_{p}} ) \\ where {v}_{i} = \{ \begin{matrix}0 & ( {\hat{u}}_{i} = 1 ) \\ 1 & ( {\hat{u}}_{i} = - 1 )\end{matrix} . \qquad ( 28 )$$

### (B-3) Parity Check

When the temporary estimated word given by the equation (28) satisfies the following equation (29), the Sum-product decoder 17 outputs an information sequence shown in the following equation (30) and stops the Sum-product decoding.

### (B-4) Increment of the Counter

When the variable l_{B} is equal to or smaller than l_{B}^{max} (l_{B}≦l_{B}^{max}), the Sum-product decoder 17 carries out a calculation of l_{B}=l_{B}+1 and shifts to the process of (B-1). In contrast, when the variable l_{B} is larger than l_{B}^{max} (l_{B}>l_{B}^{max}), the Sum-product decoder outputs the information sequence shown in the equation (30) and stops the Sum-product decoding.

As can be seen from the above description, in accordance with this Embodiment 1, because the Sum-product decoder 17 is constructed in such a way as to carry out soft-decision iterative decoding on the received signal s′(t) received by the signal receiving unit 12 by using the extended check matrix H_{d} which is a combination of the matrix D in which the differential modulation by the differential modulator 3 is replaced by a check matrix and the check matrix H for error correcting codes to carry out error correction decoding on an information sequence bᵢ, there is provided an advantage of being able to prevent degradation in the SNR ratio for the bit error rate even through the differential modulator 3 having strong resistance to phase variations is mounted in the transmitter 1. More specifically, because the phase error can be estimated with a high degree of accuracy through the iterative decoding, the degradation of about 3 dB in the gain can be prevented by applying synchronous detection also to the communication channel to which differential modulation has to be applied.

### Embodiment 2

Although the example of carrying out soft-decision iterative decoding on the received signal s′(t) received by the signal receiving unit 12 by using the extended check matrix H_{d} which is a combination of the matrix D in which the differential modulation by the differential modulator 3 is replaced by a check matrix and the check matrix H for error correcting codes is shown in above-mentioned Embodiment 1, a matrix shown in the following equation (31) can be alternatively used as the extended check matrix H_{d} when replacement is carried out on the codeword sequence by the transmitter 1 and the codeword sequence on which the replacement is carried out is differential-modulated in order to take measures against a burst error or the like.

$${H}_{d} = [ \frac{R \vert D}{H \vert 0} ] \qquad ( 31 )$$

where D is a check matrix corresponding to the differential modulation, R is a replacement matrix, 0 is a zero matrix, and H is a check matrix for error correcting codes.

In this case, when the differential modulation which the transmitter 1 carries out is, for example, differential BPSK, a concrete example of the extended check matrix H_{d} is given by the following equation (32). A codeword sequence for the extended check matrix H_{d} is shown above the equation (32). The codeword sequence consists of an information sequence b, a parity sequence P, and a transmission codeword sequence U, and the sequence outputted from the transmitter 1 to the transmission line is only the transmission codeword sequence U.

Codeword Sequence for Proposed Check Matrix Shown Below

$$\begin{matrix}Information Sequence b & P & Transmission Code Sequence V \\ & & \end{matrix} \\ {H}_{d} = \begin{matrix}1 & & & & & & & & 1 & & & & & & & \\ & & 1 & & & & & & 1 & 1 & & & & & & \\ & & & & 1 & & & & & 1 & \backslash & & & & & \\ & & & \backslash & & & & & & & \backslash & 1 & & & & \\ & & & & & & 1 & & & & & 1 & 1 & & & \\ & & & & & 1 & & & & & & & 1 & 1 & & \\ & 1 & & & & & & & & & & & & 1 & 1 & \\ & & & & & & & 1 & & & & & & & 1 & 1 \\ & & & & & & & & & & & & & & & \\ & & & & & & & & & & & & & & & \\ & & & H & & & & & & & & 0 & & & & \\ & & & & & & & & & & & & & & & \\ & & & & & & & & & & & & & & & \end{matrix} \qquad ( 32 )$$

Further, when the differential modulation which the transmitter 1 carries out is, for example, differential QPSK, a concrete example of the extended check matrix H_{d} is given by the following equation (33). A codeword sequence for the extended check matrix H_{d} is shown above the equation (33). The codeword sequence consists of an information sequence b, a parity sequence P, and a transmission codeword sequence U, and the sequence outputted from the transmitter 1 to the transmission line is only the transmission codeword sequence U.

Codeword Sequence for Proposed. Check Matrix Shown Below

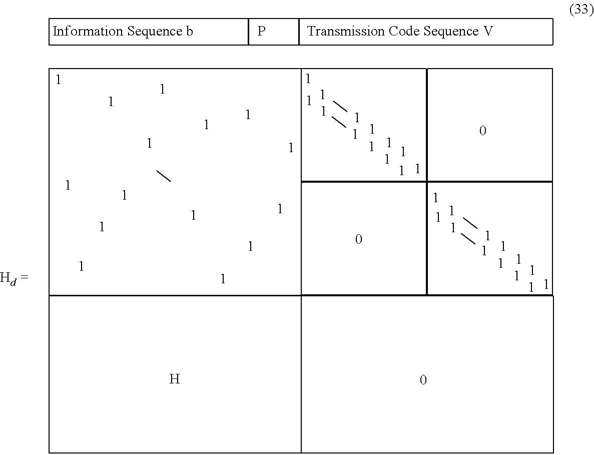

### Embodiment 3

Although the example in which there is a phase error is shown in above-mentioned Embodiment 1, by using an extended check matrix H_{d} which is an extension of a check matrix H of LDPC codes even when there is no phase error, there is also provided an advantage of enhancing the performance by adding calculation of the extended portion even when the typical LDPC decoding method in the second step is applied.

Further, although the example of estimating the phase error in the received signal yₖ by assuming that the phase error is approximated by a straight line is shown in above-mentioned Embodiment 1, the phase error can be estimated by assuming that the phase error is approximated by a curved line.

Although the example in which the transmitter 1 is assumed to use LDPC coding as error correcting codes is shown in above-mentioned Embodiment 1, any type of error correcting code can be used as long as a soft decision bit can be estimated from error correcting codes.

The present invention can be applied to any communication devices, such as optical communication devices, radio communication devices, cable communication devices, and satellite communication devices.

While the invention has been described in its preferred embodiments, it is to be understood that an arbitrary combination of two or more of the above-mentioned embodiments can be made, various changes can be made in an arbitrary component in accordance with any one of the above-mentioned embodiments, and an arbitrary component in accordance with any one of the above-mentioned embodiments can be omitted within the scope of the invention.

### INDUSTRIAL APPLICABILITY

Because the receiver in accordance with the present invention includes the signal receiver that receives a modulated signal of a codeword series outputted to the transmission line from the transmitter that carries out error correction coding on an information sequence so as to generate the codeword series and also carries out differential modulation on the codeword series, and the error correction decoder that carries out soft-decision iterative decoding on the received signal received by the signal receiver by using an extended check matrix which is a combination of a matrix in which the differential modulation is replaced by a check matrix and a check matrix for error correcting codes to carry out error correction decoding on the information sequence, and can prevent degradation in the SNR ratio to the bit error rate even though a differential modulator having strong resistance to phase variations is mounted in the transmitter, the receiver is suitable for use in a communication device that carries optical communications.

### EXPLANATIONS OF REFERENCE NUMERALS

1 transmitter, 2 LDPC coder, 3 differential modulator, 11 receiver, 12 signal receiving unit (signal receiver), 13 carrier sensing unit, 14 PLL, 15 frame synchronization unit, 16 demodulator (error correction decoding unit), 17 Sum-product decoder (error correction decoder).

1. A receiver comprising:
a signal receiver that receives a modulated signal of a codeword series outputted to a transmission line from a transmitter that carries out error correction coding on an information sequence so as to generate the codeword series and also carries out differential modulation on said codeword series; and
an error correction decoder that carries out soft-decision iterative decoding on the received signal received by said signal receiver by using an extended check matrix which is a combination of a matrix in which said differential modulation is replaced by a check matrix and a check matrix for error correcting codes to carry out error correction decoding on said information sequence.

2. A communication device including a transmitter that carries out error correction coding on an information sequence so as to generate a codeword series, and that also carries out differential modulation on said codeword series and outputs a modulated signal of said codeword series to a transmission line, and a receiver that receives the modulated signal of the codeword series outputted from said transmitter to the transmission line, and that carries out error correction decoding on the information sequence, wherein said receiver includes:
a signal receiver that receives the modulated signal of the codeword series outputted from said transmitter to the transmission line; and an error correction decoder that carries out soft-decision iterative decoding on the received signal received by said signal receiver by using an extended check matrix which is a combination of a matrix in which said differential modulation is replaced by a check matrix and a check matrix for error correcting codes to carry out error correction decoding on said information sequence.

3. The communication device according to claim 2, wherein the error correction decoder carries out the soft-decision iterative decoding on the received signal received by the signal receiver by using the extended check matrix and estimates a phase error of said received signal by using a soft decision bit acquired from results of the decoding and also corrects said received signal by using said phase error, and carries out soft-decision iterative decoding on the corrected received signal by using said extended check matrix to carry out the error correction decoding on the information sequence.

4. The communication device according to claim 2, wherein the error correction decoder uses a matrix H_{d} shown below as the extended check matrix.
$${H}_{d} = [ \frac{I \vert D}{H \vert 0} ]$$
where D is the check matrix corresponding to the differential modulation, I is a unit matrix, 0 is a zero matrix, and H is the check matrix for error correcting codes.

5. The communication device according to claim 3, wherein the error correction decoder uses a matrix H_{d} shown below as the extended check matrix.
$${H}_{d} = [ \frac{I \vert D}{H \vert 0} ]$$
where D is the check matrix corresponding to the differential modulation, I is a unit matrix, 0 is a zero matrix, and H is the check matrix for error correcting codes.

6. The communication device according to claim 2, wherein when replacement is carried out on the codeword series by the transmitter and the differential modulation is carried out on the codeword series on which the replacement is carried out, the error correction decoder uses a matrix H_{d} shown below as the extended check matrix.
$${H}_{d} = [ \frac{R \vert D}{H \vert 0} ]$$
where D is the check matrix corresponding to the differential modulation, R is a replacement matrix, 0 is a zero matrix, and H is the check matrix for error correcting codes.

7. The communication device according to claim 3, wherein when replacement is carried out on the codeword series by the transmitter and the differential modulation is carried out on the codeword series on which the replacement is carried out, the error correction decoder uses a matrix H_{d} shown below as the extended check matrix.
$${H}_{d} = [ \frac{R \vert D}{H \vert 0} ]$$
where D is the check matrix corresponding to the differential modulation, R is a replacement matrix, 0 is a zero matrix, and H is the check matrix for error correcting codes.

8. A communication method including the steps of a transmitter carrying out error correction coding on an information sequence so as to generate a codeword series, and also carrying out differential modulation on said codeword series and outputting a modulated signal of said codeword series to a transmission line, and a receiver receiving the modulated signal of the codeword series outputted from said transmitter to the transmission line, and carrying out error correction decoding on the information sequence, wherein said receiver carries out:
a signal receiving process step of receiving the modulated signal of the codeword series outputted from said transmitter to the transmission line; and
an error correction decoding process step of carrying out soft-decision iterative decoding on the received signal received in said signal receiving process step by using an extended check matrix which is a combination of a matrix in which said differential modulation is replaced by a check matrix and a check matrix for error correcting codes to carry out error correction decoding on said information sequence.
